(19) United States
(12) Patent Application Publication
(10) Pub. No.: US 2024/0379841 A1
(43) Pub. Date: Nov. 14, 2024

(54) SEMICONDUCTOR DEVICE

(71) Applicant: Vanguard International Semiconductor Corporation, Hsinchu (TW)

(72) Inventors: Tse-Hsiao LIU, Hsinchu City (TW); Po-Hao CHIU, Zhunan Township (TW); Nai-Lun CHENG, Zhubei City (TW); Pi-Kuang CHUANG, Hsinchu City (TW); Chih-Hung LIN, Taichung City (TW); Ching-Yi HSU, Hsinchu City (TW)

(73) Assignee: Vanguard International Semiconductor Corporation, Hsinchu (TW)

(21) Appl. No.: 18/313,501

(22) Filed: May 8, 2023

(51) Int. Cl. H01L 29/78; H01L 29/06; H01L 29/10

(52) U.S. Cl. CPC H01L 29/7816; H01L 29/0653; H01L 29/1095

(57) ABSTRACT

A semiconductor device includes a first well region having the first conductivity type and a second well region having the second conductivity type formed in a substrate having the first conductivity type. An isolation component and a third well region are formed in the second well region. The third well region has the first conductivity type and is in contact with the bottom surface of the isolation component. A first doping region is formed in the first well region and a second doping region is formed in the second well region. The first and second doping regions have the second conductivity type and are disposed at opposite sides of the gate structure. The interface between the first well region and the second well region is positioned between the isolation component and the first doping region. The interface is separated from the third well region by a lateral distance.

### BACKGROUND

### Technical Field

The disclosure relates to a semiconductor device, and in particular it relates to a semiconductor device that has low-on resistance.

### Description of the Related Art

A semiconductor device includes a substrate and circuit components disposed on the substrate. Semiconductor devices have been widely used in various electronic products, such as personal computers, mobile phones, digital cameras and other electronic devices. The evolution of semiconductor devices continues to influence and improve the modern lifestyle. Laterally diffused metal oxide semiconductor (LDMOS) devices have been widely used due to the thermal stability, frequency stability, and good heat dissipation. Also, LDMOS devices are compatible with other MOS fabrication processes. For example, LDMOS devices have been used in display driver integrated circuit (IC) components, power supply, power management, communication, automotive electronics or industrial control and other fields.

However, the current processes for manufacturing semiconductor devices are not satisfactory in every respect. For example, in order to achieve a high on-resistance that is required by the semiconductor device in some applications, the length of the semiconductor device is extended to reduce the on-current in the existing laterally diffused metal oxide semiconductor device, thereby increasing the lateral size of the semiconductor device. In addition, each semiconductor device requires extra lateral space for setting the extended portion of the semiconductor device, thereby reducing the number of semiconductor devices that are fabricated on a wafer. Therefore, it is necessary to develop a new semiconductor device and manufacturing method to solve the aforementioned problems.

### SUMMARY

Some embodiments of the present disclosure provide semiconductor device. A semiconductor device includes a substrate, a first well region, a second well region, an isolation component, a third well region, a gate structure, a first doping region, and a second doping region. The substrate has the first conductivity type. The first well region is formed in the substrate and has the first conductivity type. The second well region is formed in the substrate and has the second conductivity type. The isolation component is formed in the second well region. The third well region is formed in the second well region. The third well region has the first conductivity type and is in contact with the bottom surface of the isolation component. The gate structure is formed on the substrate. The gate structure spans over the first well region and the second well region. The first doping region is formed in the first well region. The second doping region is formed in the second well region. The first doping region and the second doping region have the second conductivity type and are disposed at opposite sides of the gate structure. The interface between the first well region and the second well region is positioned between the isolation component and the first doping region. The interface is separated from the third well region by a lateral distance.

A detailed description is given in the following embodiments with reference to the accompanying drawings.

### BRIEF DESCRIPTION OF THE DRAWINGS

The embodiments of the disclosure can be more fully understood by reading the subsequent detailed description and examples with references made to the accompanying drawings. For clarity of illustration, various elements in the drawings may not be drawn to scale, wherein:

FIG. 1A, FIG. 1B, FIG. 1C, FIG. 1D and FIG. 1E illustrate cross-sectional views of intermediate stages of a method for forming a semiconductor device in accordance with some embodiments of the present disclosure.

FIG. 2 is a top view of a semiconductor device according to some embodiments of the present disclosure.

FIG. 3A, FIG. 3B and FIG. 3C illustrate cross-sectional views of intermediate stages of a method for forming a semiconductor device in accordance with some embodiments of the present disclosure.

FIG. 4 is a cross-sectional view of a semiconductor device in accordance with some embodiments of the present disclosure.

### DETAILED DESCRIPTION

The following description provides various embodiments, or examples, for implementing different features of the present disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numbers and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, the term that is described with “about”, “substantially”, “approximately” or the like is intended to encompass numbers that are within a reasonable range including the number described, such as within +/−20% of a given numerical value, preferably within +/−10%, and more preferably +/−within 5%, or within +/−3%, or within +/−2%, or within +/−1%, or within 0.5% of a given numerical value. The numerical value given here is an approximate value. That is, in the absence of specific description of “about”, “substantially” and “approximately”, the given numerical value can still imply “about”, “substantially” and “approximately”.

It can be understood that although the terms “first”, “second”, “third”, etc. may be used herein to describe various elements, components, regions, layers and/or portions, these elements, components, regions, layers and/or portions should not be limited by these terms, and these terms are only used to distinguish different elements, components, regions, layers and/or portions. Therefore, a first element, component, region, layer and/or portions discussed below may be referred to as a second element, component, region, layer and/or portion without departing from the spirit of the disclosure.

Some embodiments are described below. Although the steps in some embodiments described are performed in a specific order, the steps can also be performed in other logical orders. In some embodiments, some of the described steps may be replaced or eliminated. In some embodiments, Additional steps can also be provided before, during, and after the described steps in the method that is provided in some embodiments of the present disclosure. In addition, it should be understood that other components may be added to the semiconductor device in some embodiments of the present disclosure. In some other embodiments, some components can be replaced or eliminated.

Embodiments provide semiconductor devices and methods for manufacturing the same. In some embodiments, a semiconductor device that includes a well region (such as the third well region described in the embodiment) adjacent to an isolation component is provided. The well region and the drain region of the semiconductor device have different conductivity types. The isolation component is adjacent to a gate structure and a drain region. Accordingly, the on-resistance (Ron) of the semiconductor device can be increased and the on-current of the semiconductor device can be reduced. In addition, in some embodiments, the well region (such as the third well region described below) that is arranged for reducing the on-current of the semiconductor device does not occupy additional lateral space of the substrate, and therefore does not increase the lateral size of the semiconductor device. In addition, the method for forming a semiconductor device in the embodiments has a relatively simple manufacturing process and is compatible with existing manufacturing processes. In the embodiments, the semiconductor device with low on-current can be formed by using the embodied method that meets requirements of the application device without expensive manufacturing costs.

In addition, the embodiments can be applied to metal-oxide-semiconductor (MOS) devices, such as laterally diffused metal-oxide-semiconductor (LDMOS) devices. In some of the embodiments described below, a LDMOS device is used to illustrate relative structures of a semiconductor device. However, the present disclosure is not limited thereto. Some embodiments of the present disclosure can be applied to other types of semiconductor devices.

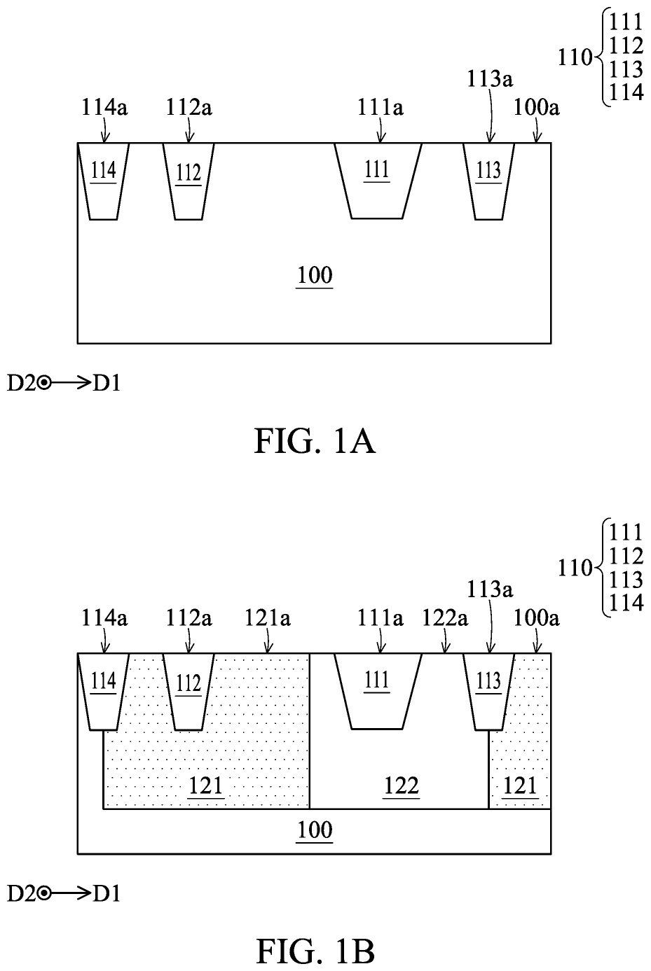

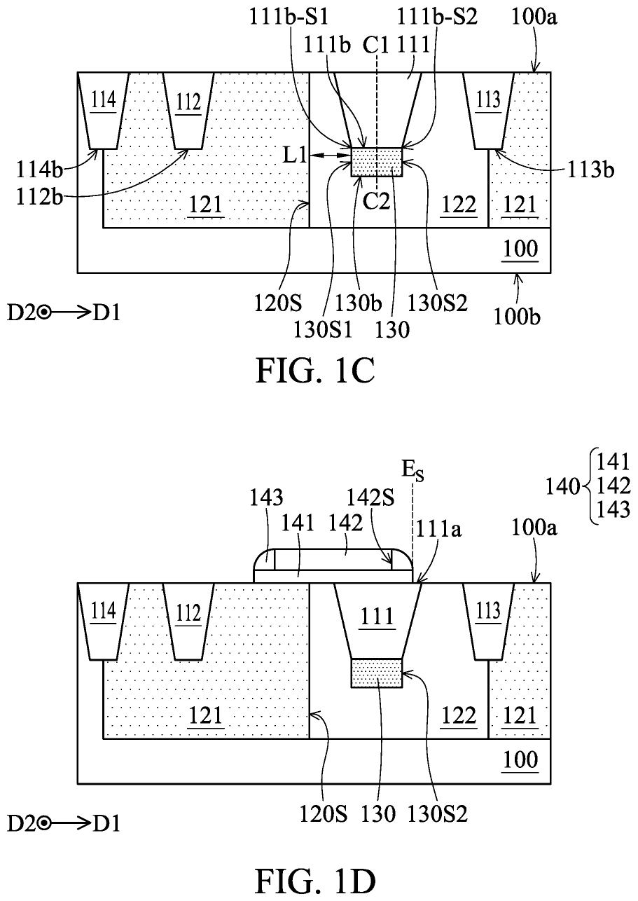

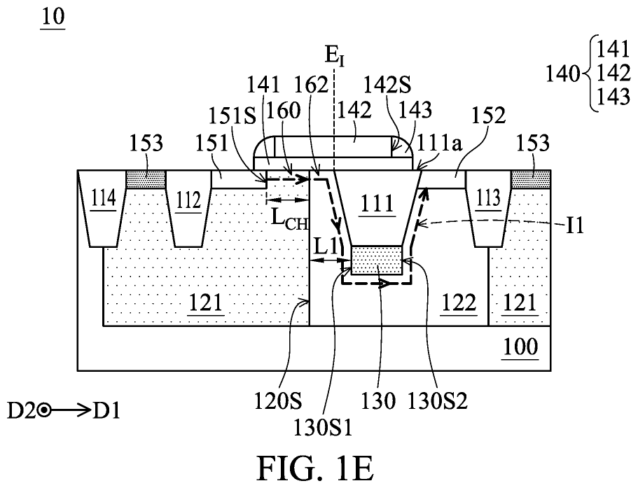

FIG. 1A-FIG. 1E illustrate cross-sectional views of intermediate stages of a method for forming a semiconductor device 10, in accordance with some embodiments of the present disclosure.

Referring to FIG. 1A, in some embodiments, a substrate 100 is provided. The substrate 100 may include any base material suitable for forming the semiconductor devices. For example, the substrate 100 may be a bulk semiconductor substrate or a composite substrate formed of different materials. In some embodiments, the substrate 100 may include one or more elemental semiconductor materials, such as silicon or germanium. In some embodiments, the substrate 100 includes one or more compound semiconductors, such as gallium nitride (GaN), silicon carbide, gallium arsenide, gallium phosphide, indium phosphide, indium arsenide, and/or indium antimonide. In some embodiments, the substrate 100 includes alloy semiconductors, such as silicon-germanium (SiGe), gallium arsenide phosphide (GaAsP), aluminum indium arsenide (AlInAs), aluminum gallium arsenide (AlGaAs), gallium indium arsenide (GaInAs), gallium indium phosphide (GaInP), gallium indium arsenide phosphide (GaInAsP), the like, or a combination of the foregoing materials. In some embodiments, the substrate 100 can be a semiconductor-on-insulator (SOI) substrate. The SOI substrate may include a bottom base, a buried oxide layer disposed on the bottom base, and a semiconductor layer disposed on the buried oxide layer.

In addition, in some embodiments, the substrate 100 can be doped with p-type dopants or n-type dopants to form a substrate with the first conductivity type. In this exemplified embodiment, the first conductivity type is p-type. For example, the aforementioned p-type dopants can be boron (B), aluminum, gallium (Ga), boron-difluoride (BF₂), the like, or a combination of the foregoing materials. The aforementioned n-type dopants can be nitrogen, phosphorus (P), Arsenic (As), antimony (Sb), the like, or a combination of the foregoing materials.

Next, an isolation structure 110 is formed in the substrate 100, in accordance with some embodiments of the present disclosure. The isolation structure 110 includes several isolation components. Those isolation components are, for example, separated from each other in the first direction D1 and extend in the second direction D2. The second direction D2 is, for example, perpendicular to the first direction D1. In addition, the isolation components extend from the top surface 100a of the substrate 100 toward the inside of the substrate 100. In this exemplified embodiment, the isolation structure 110 includes a first isolation component 111, a second isolation component 112, a third isolation component 113 and a fourth isolation component 114, as shown in FIG. 1A. In addition, in this embodiment, the top surface of the isolation structure 110 (such as the top surface 111a of the first isolation component 111, the top surface 112a of the second isolation component 112, the top surface 113a of the third isolation component 113 and the top surface 114a of the fourth isolation component 114) is coplanar with the top surface 100a of the substrate 100.

In some embodiments, the above-mentioned isolation structure 110 is formed of a dielectric material. Examples of the dielectric material include silicon oxide, silicon nitride, silicon oxynitride, another suitable dielectric material, or a combination of the foregoing dielectric materials. In addition, in some embodiments, the above-mentioned isolation structure 110 can be formed by a local oxidation of silicon (LOCOS) isolation process, a shallow trench isolation (STI) process, or a combination of the foregoing processes. In this exemplified embodiment, the isolation structure 110 includes shallow trench isolation (STI) components.

Referring to FIG. 1B, in some embodiments, a first well region 121 is formed in the substrate 100, and the first well region 121 has the first conductivity type, which may be p-type. The first well region 121 and the substrate 100 have the same conductivity type. In addition, in some embodiments, the second well region 122 is formed in the substrate 100, and the second well region 122 has the second conductivity type, which may be n-type. The second well region 122 and the first well region 121 have different conductivity types. In this exemplified embodiment, the second well region 122 is adjacent to the first well region 121. The first well region 121 and the second well region 122 extend from the top surface 100a of the substrate 100 to the inside of the substrate 100.

In some embodiments, as viewed from the top of the substrate 100, the first well region 121 surrounds the second well region 122. There is an interface between the first well region 121 and the second well region 122. In addition, the top surface 121a of the first well region 121 and the top surface of the second well region 122 are substantially coplanar with the top surface of the isolation structure 110 and the top surface 100a of the substrate 100. Specifically, in this exemplified embodiment, the top surface 121a of the first well region 121 and the top surface 122a of the second well region 122 are substantially coplanar with the top surface 111a of the first isolation component 111, the top surface 112a of the second isolation component 112, the top surface 113a of the third isolation component 113, the top surface 114a of the fourth isolation component 114 and the top surface 100a of the substrate 100.

In the applications of some semiconductor devices, the first well region 121 can be a p-type well, and the second well region 122 can be an n-type well. In addition, in the applications of some semiconductor devices, the first well region 121 can be referred to a high voltage p-type well region (HVPW), and the second well region 122 can be referred to a high voltage n-type well region (HVNW).

The first well region 121 and the second well region 122 can be formed by an ion implantation process, in accordance with some embodiments of the present disclosure. For example, the first well region 121 and the second well region 122 with different conductivity types can be formed by two individual ion implantation processes. In some embodiments, the doping concentration of the first well region 121 is, for example but not limited to, in the range of about 1E16 cm⁻³ to about 1E18 cm⁻³. The doping concentration of the second well region 122 is, for example but not limited to, in the range of about 1E16 cm⁻³ to about 1×10¹⁸ cm⁻³.

In addition, each isolation component of the isolation structure 110 is positioned in a corresponding well region, in accordance with some embodiments of the present disclosure. Specifically, in this exemplified embodiment, the first isolation component 111 is positioned in the second well region 122, and the second isolation component 112 is positioned in the first well region 121, as shown in FIG. 1B. In addition, in one example, the third isolation component 113 is positioned in the first well region 121 and the second well region 122, and the fourth isolation component 114 is positioned in the first well region 121 and the second well region 122. The fourth isolation component 114 and the third isolation component 113 are positioned on opposite sides of the first isolation component 111 and the second isolation component 112.

Referring to FIG. 1C, in some embodiments, a third well region 130 is formed in the second well region 122, and the third well region 130 has the first conductivity type, which may be p-type. The third well region 130 and the second well region 122 have different conductivity types. The third well region 130 is separated from other isolation components other than the first isolation component 111 in the first direction D1. For example, the third well region 130 is separated from the second isolation component 112, the third isolation component 113 and the fourth isolation component 114 in the first direction D1. The third well region 130 substantially extends in the second direction D2.

In some embodiments, the third well region 130 is adjacent to the first isolation component 111. For example, the third well region 130 is in direct contact with the bottom surface 111b of the first isolation component 111. Specifically, in this exemplified embodiment, the third well region 130 directly covers a portion of the bottom surface 111b of the first isolation component 111 or the entire bottom surface 111b of the first isolation component 111. In addition, the third well region 130 is closer to the bottom surface 100b of the substrate 100 than the isolation components. More specifically, compared to the bottom surface 111b of the first isolation component 111, the bottom surface 112b of the second isolation component 112, the bottom surface 113b of the third isolation component 113 and the bottom surface 114b of the fourth isolation component 114, the bottom surface 130b of the third well region 130 is further inside the substrate 100. That is, the bottom surface 130b of the third well region 130 is closer to the bottom surface 100b of the substrate 100.

In addition, the opposite sidewalls of the third well region 130 can be substantially aligned with the opposite sides of the bottom surface 111b of the first isolation component 111, in accordance with some embodiments of the present disclosure. In some other embodiments, the opposite sidewalls of the third well region 130 may not be aligned with the opposite sides of the bottom surface 111b of the first isolation component 111.

Specifically, in this exemplified embodiment, the third well region 130 includes the first sidewall 130S1 and the second sidewall 130S2 opposite the first sidewall 130S1. The first sidewall 130S1 is adjacent to the second isolation component 112, and the second sidewall 130S2 is adjacent to the third isolation component 113. In addition, the bottom surface 111b of the first isolation component 111 includes opposite sides 111b-S1 and 111b-S2. In one example, the first sidewall 130S1 of the third well region 130 is substantially aligned with the side 111b-S1 of the bottom surface 111b of the first isolation component 111, as shown in FIG. 1C. In another example, the first sidewall 130S1 of the third well region 130 protrudes from the side 111b-S1 of the bottom surface 111b of the first isolation component 111. In addition, in one example, the second sidewall 130S2 of the third well region 130 is substantially aligned with the other side 111b-S2 of the bottom surface 111b of the first isolation component 111, as shown in FIG. 1C. In another example, the second sidewall 130S2 of the third well region 130 is not aligned with the other side 111b-S2 of the bottom surface 111b of the first isolation component 111. For example, the second sidewall 130S2 does not protrude from the side 111b-S2 of the bottom surface 111b of the first isolation component 111.

Therefore, according to the aforementioned descriptions, in some embodiments, the bottom surface 111b of the first isolation component 111 can be completely covered by the third well region 130, so that the bottom surface 111b does not in contact with the second well region 122. In some other embodiments, the bottom surface 111b of the first isolation component 111 can be partially covered by the third well region 130, so that a portion of the bottom surface 111b is exposed in the second well region 122.

In addition, as shown in FIG. 1C, the interface 120S between the first well region 121 and the second well region 122 is positioned between the first isolation component 111 and the second isolation component 112, in accordance with some embodiments of the present disclosure. The first sidewall 130S1 of the third well region 130 is separated from the interface 120S. For example, the first sidewall 130S1 of the third well region 130 is separated from the interface 120S by a lateral distance L1 in the first direction D1. In other words, the third well region 130 is not in contact with the interface 120S. That is, the third well region 130 is not in contact with the first well region 121. According to some embodiments, a predetermined on-current value of a semiconductor device can be achieved by adjusting the lateral distance L1. The smaller the lateral distance L1 is, the smaller the on-current of the semiconductor device 10 is.

In addition, the arrangement of the third well region 130 may be or may not be offset from the first isolation component 111, and this disclosure is not limited thereto. Typically, the opposite sidewalls of a feature component has a central line that extends in the second direction D2, wherein the opposite sidewalls are separated in the first direction D1. Alignment between the central lines of the upper feature and the lower feature can be used to determine whether the upper feature and the lower feature are offset from each other. As shown in FIG. 1C, the central line C1 of the first isolation component 111 is aligned with the central line C2 of the third well region 130, That is, the third well region 130 is not offset from the overlying first isolation component 111, in accordance with some embodiments of the present disclosure.

In addition, in some embodiments, the third well region 130 can be formed adjacent to the bottom surface 111b of the first isolation component 111 by an ion implantation process. After the ion implantation process, the implanted dopants can be activated by a heat treatment. The aforementioned heat treatment is, for example, a rapid thermal annealing (RTA) process or another suitable method. In an application of a laterally diffused metal-oxide-semiconductor (LDMOS) device, the second well region 122 with the second conductivity type (for example, n-type) can act as a drift region of the semiconductor device 10. It should be noted that, in some embodiments, the doping concentration of the third well region 130 having the first conductivity type (for example, p-type) is greater than the doping concentration of the second well region 122, so as to facilitate the second conductivity type (for example, n-type) changing to the first conductivity type (for example, p-type). In some embodiments, the doping concentration of the third well region 130 is, for example but not limited to, in the range of about 1E17 cm⁻³ to about 1E19 cm⁻³.

Referring to FIG. 1D, a gate structure 140 is formed on the substrate 100 (for example, on the top surface 100a of the substrate 100), and the gate structure 140 is formed over and across the first well region 121 and the second well region 122, in accordance with some embodiments of the present disclosure. In some embodiments, the gate structure 140 includes a gate dielectric layer 141, a gate electrode 142 on the gate dielectric layer 141, and gate spacers 143 on opposite sides of the gate electrode 142.

In addition, the gate structure 140 is positioned above the third well region 130. A lateral edge E_{S} of the gate structure 140 that is closer to the first isolation component 111 is positioned on the top surface 111a of the first isolation component 111, in accordance with some embodiments of the present disclosure. The gate structure 140 in the first direction D1 does not exceed the top surface 111a of the first isolation component 111. Specifically, in this exemplified embodiment, the sidewall 142S of the gate electrode 142 that is closer to the first isolation component 111 is positioned above the third well region 130, and not beyond the second sidewall 130S2 of the third well region 130, as shown in FIG. 1D.

In some embodiments, the gate dielectric layer 141 may include a single layer or multiple layers of gate dielectric material. The gate dielectric layer 141 may include silicon oxide, silicon nitride, silicon oxynitride, the like, or a combination of the foregoing materials. In some embodiments, a gate dielectric material layer can be formed on the substrate 100 by an oxidation process, a deposition process, another suitable process, or a combination of the foregoing processes. The aforementioned oxidation process includes, for example, a dry oxidation process or a wet oxidation process. The aforementioned deposition process includes, for example, a chemical deposition process. In some embodiments, a gate dielectric material layer can be formed by using a thermal oxidation method or another suitable method, and then patterned to form the gate dielectric layer 141 by using a photolithographic patterning process, an etching process and another suitable process.

In addition, in some embodiments, the gate dielectric layer 141 may include a high-k dielectric material, such as a dielectric material with a dielectric constant greater than 3.9. Examples of the aforementioned high-k dielectric material include (but not limited to) metal oxides, metal nitrides, metal silicides, metal aluminates, zirconium silicates, zircoaluminate, or a combination of the foregoing materials. In some examples, the gate dielectric layer 141 may include HfO₂, LaO₂, TiO₂, ZrO₂, Al₂O₃, Ta₂O₃, HfZrO, ZrSiO₂, HfSiO₄, another high dielectric constant material, or a combination of the foregoing materials. A gate dielectric material layer that includes a high-k dielectric material can be formed by physical vapor deposition (PVD), chemical vapor deposition (CVD), atomic layer deposition (ALD), another suitable deposition process, spin coating (spin coating) process, or a combination of the foregoing processes. In some embodiments, a gate dielectric material layer that includes a high-k dielectric material can be deposited on the substrate by a plasma enhanced chemical vapor deposition (PECVD), and then patterned by a suitable photolithographic patterning process and an etching process to form the gate dielectric layer 141.

In some embodiments, the gate electrode 142 may include a single layer or multiple layers of gate electrode material. In some embodiments, the gate electrode 142 includes amorphous silicon, polysilicon, metal nitride, conductive metal oxide, metal, another suitable material, or a combination of the foregoing materials. The aforementioned metals may include aluminum (Al), molybdenum (Mo), tungsten (W), titanium (Ti), tantalum (Ta), platinum (Pt), hafnium (Hf), or a combination of the foregoing metals, but are not limited to those metal. The aforementioned conductive metal oxide may include ruthenium metal oxide or indium tin metal oxide, but is not limited to these materials. In some embodiments, a gate electrode material layer is formed by using chemical vapor deposition, sputtering, resistive heating evaporation, electron beam evaporation, pulsed laser deposition, or another suitable method. Next, the gate electrode material layer is patterned to form the gate electrode 142 by using a suitable photolithographic patterning process and an etching process. In addition, the aforementioned chemical vapor deposition can be, for example, a low pressure chemical vapor deposition (LPCVD) process, a low temperature chemical vapor deposition (LTCVD) process, a rapid thermal chemical vapor deposition (RTCVD) process, a plasma enhanced chemical vapor deposition (PECVD) process, an atomic layer deposition (ALD) process, another suitable method, or a combination of the foregoing processes.

In some embodiments, a gate spacer material layer (not shown) is deposited over the substrate 100 and covers the gate dielectric material layer and the gate electrode 142. Next, a portion of the gate spacer material layer and a portion of the gate dielectric material layer are removed to form gate spacers 143 and the gate dielectric layer 141 by using a suitable patterning process and etching process. The gate spacers 143 are formed on the sidewalls of the gate electrode 142, and a gate dielectric layer 141 is formed underlying the gate electrode 142. In some embodiments, the gate spacers 143 may include a single layer or multiple layers of gate spacer material. The gate spacers 143 may include silicon oxide, silicon nitride, silicon oxynitride, another suitable material, or a combination of the foregoing materials.

Referring to FIG. 1E, a first doping region 151 is formed in the first well region 121 and a second doping region 152 is formed in the second well region 122, in accordance with some embodiments of the present disclosure. The first doping region 151 and second doping region 152 have the second conductivity type, such as n-type. In addition, the first doping region 151 and the second doping region 152 are positioned at opposite sides of the gate structure 140. In some embodiments, the first isolation component 111 and the third well region 130 are positioned between the first doping region 151 and the second doping region 152, as shown in FIG. 1E.

In addition, in this exemplified embodiment, the interface 120S between the first well region 121 and the second well region 122 is located between the first isolation component 111 and the first doping region 151. As shown in FIG. 1E, the first sidewall 130S1 of the third well region 130 is adjacent to the first doping region 151, and the second sidewall 130S2 that is opposite to the first sidewall 130S1 is adjacent to the second doping region 152. In some embodiments, a channel region 160 of the semiconductor device 10 is formed between the sidewall 151S of the first doping region 151 and the interface 120S. The channel region 160 that is under the gate structure 140 has a channel length LCH in the first direction D1.

In some embodiments, the first doping region 151 and the second doping region 152 can be formed by an ion implantation process. After the ion implantation is performed, the dopants can be activated and diffused by a heat treatment (such as rapid thermal annealing or another suitable method). In the application of a laterally diffused metal-oxide-semiconductor (LDMOS) device, the first doping region 151 and the second doping region 152 that have the second conductivity type (such as n-type) can function as a source region and a drain region of the semiconductor device 10, respectively. In some embodiments, the doping concentration of the first doping region 151 and the second doping region 152 is, for example (but not limited to), in the range of about 1E18 cm⁻³ to about 1E21 cm⁻³. In some embodiments, the doping concentration of the first doping region 151 is greater than the doping concentration of the first well region 121, and the doping concentration of the second doping region 152 is greater than the doping concentration of the second well region 122.

In addition, in some embodiments, after the first doping region 151 and the second doping region 152 are formed, a third doping region 153 is further formed in the first well region 121. The third doping region 153 has the first conductivity type, for example, p-type. In this exemplified embodiment, the first doping region 151 is positioned between the third doping region 153 and the first isolation component 111. More specifically, the third doping region 153 is positioned between the second isolation component 112 and the fourth isolation component 114. In an application of a laterally diffused metal-oxide-semiconductor (LDMOS) device, the third doping region 153 that has the first conductivity type (for example, p-type) functions as a bulk region of the semiconductor device 10. In some embodiments, the doping concentration of the third doping region 153 is, for example (but not limited to), in the range of about 1E18 cm⁻³ to about 1E21 cm⁻³.

It should be noted that the doping concentration of the third well region 130 having the first conductivity type (for example, p-type) is lower than the doping concentration of the first doping region 151 and lower than the doping concentration of the second well region 152, in accordance with some embodiments of the present disclosure. The doping concentration of the third well region 130 is also lower than the doping concentration of the third doping region 153. Accordingly, the semiconductor device 10 has a sufficiently high breakdown voltage (BDV).

When the semiconductor device 10 of the embodiment is in operation, the current flows from the first doping region 151 (such as a source region of the semiconductor device) to the second doping region 152 (such as a drain region of the semiconductor device) by passing through the channel region 160 and along a sidewall of the first isolation component 111, the first sidewall 130S1 of the third well region 130, the bottom surface of the third well region 130, the second sidewall 130S2 of the third well region 130 and another sidewall of the first isolation component 111. The current flow direction is illustrated by the dotted line I1 in FIG. 1E. Compared to the current of the conventional semiconductor device that flows along the surfaces of the isolation component, the current of the semiconductor device 10 of the embodiment will flow into a deeper portion of the substrate 100 and have a longer current path, thereby reducing the current density when the semiconductor device 10 is in the on-state. That is, the current that flows in the second well region 122 (the drift region) of the semiconductor device 10 has a longer current path. In addition, according to the arrangement of the third well region 130 of the embodiment, it has restriction effect on the current flowing into the region 162 (i.e., the region between the interface 120S and the side edge E_{I} of the first isolation component 111), thereby reducing the current into the second well region 122 (drift region). Thus, the current density can be decreased when the semiconductor device 10 is in the on-state. According to the descriptions above, the on-state current of the semiconductor device 10 that has the third well region 130 can be decreased, in accordance with some embodiments of the present disclosure. In addition, the closer the third well region 130 is to the interface 120S (that is, the smaller the lateral distance L1 as discussed referring to FIG. 1C), the smaller the on-state current of the semiconductor device 10 is.

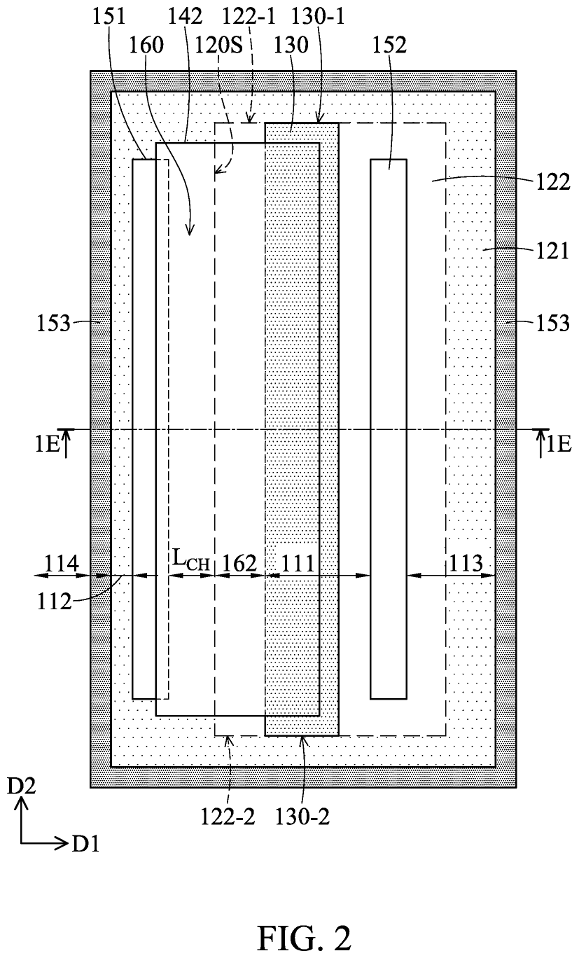

FIG. 2 is a top view of a semiconductor device according to some embodiments of the present disclosure. Please refer to FIG. 1E and FIG. 2. FIG. 1E is, for example, a schematic cross-sectional view taken along a section line 1E-1E in FIG. 2. The features/components in FIG. 2 similar or identical to the features/components in FIG. 1E are designated with similar or the same reference numbers. The details of those similar or the identical features/components can be referred to the above-mentioned descriptions and are not repeated herein.

Referring to FIG. 2, according to some embodiments, as viewed from the top of the substrate, the first well region 121 that has the first conductivity type (for example, p-type) surrounds the second well region 122 that has the second conductivity type (for example, n-type). The gate structure 140 is formed above and across the first well region 121 and the second well region 122. The first doping region 151 (for example, used as a source region of the semiconductor device) and the second doping region 152 (for example, used as a drain region of the semiconductor device) that have the second conductivity type (for example, n-type) are separated from each other in the first direction D1 and extend in the second direction D2. The first doping region 151 and the second doping region 152 are positioned on opposite sides of the gate structure 140, respectively. In some embodiments, as viewed from the top of the substrate, the third doping region 153 (for example, used as a bulk region of the semiconductor device) that has the first conductivity type (for example, p-type) is a ring-shaped doping region, which encloses the first doping region 151, the gate structure 140, the second well region 122 and the second doping region 152.

In addition, in some embodiments, as viewed from the top of the substrate, the third well region 130 is strip-shaped. The third well region 130, the first doping region 151 and the second doping region 152 extend in the same direction (for example, in the second direction D2). The ring-shaped third doping region 153 also surrounds the third well region 130.

More specifically, in this exemplified embodiment, both sides of the strip-shaped third well region 130 are respectively separated from the first doping region 151 and the second doping region 152 in the first direction D1, as shown in FIG. 2. The third well region 130, the first doping region 151 and the second doping region 152 extend in the second direction D2 that is different from the first direction D1. The first isolation component 111 and the third well region 130 extend between the first doping region 151 and the second doping region 152. Therefore, in this exemplified embodiment, the third well region 130 extends under the first isolation component 111 and corresponds to one side of the gate structure 140. The third well region 130 does not surround the first doping region 151. In addition, the third well region 130 does not surround the gate structure 140, as shown in FIG. 2.

In some embodiments, the third well region 130 can be electrically connected to the third doping region 153 (for example, used as a bulk region of the semiconductor device). The strip-shaped third well region 130 may extend to the second well region 122 (as shown in FIG. 2) or beyond the second well region 122 to contact the first well region 121. More specifically, the two edges 130-1 and 130-2 of the third well region 130 that are separated in the second direction D2 may exceed the two edges 122-1 and 122-2 of the second well region 122 that are separated in the second direction D2, respectively. In other words, in some examples, an extension length of the third well region 130 in the second direction D2 is greater than an extension length of the second well region 122 in the second direction D2. As shown in FIG. 2, the third doping region 153 is in contact with the first well region 121, so that the third well region 130 that is in contact with the first well region 121 is also electrically connected to the third doping region 153. In some embodiments, when the semiconductor device is in operation, the third doping region 153 is grounded, and the electrical charges accumulated in the third well region 130 can be released through the third doping region 153, so that the electrical performance of the semiconductor device (for example, the current-voltage (I-V) curve) is more stable. However, the present disclosure is not limited thereto.

In some other embodiments, the third well region 130 can be electrically insulated from the first well region 121 and the third doping region 153. That is, the third well region 130 is in a floating state. For example, the strip-shaped third well region 130 is retracted within the second well region 122 without contacting the first well region 121 (not shown). More specifically, in this exemplified embodiment, the two edges 130-1 and 130-2 of the third well region 130 that are separated in the second direction D2 do not in contact with or not exceed the two edges 122-1 and 122-2 of the second well region 122 that are separated in the second direction D2.

Details of the arrangement, materials and manufacturing methods of the components, such as the substrate 100, the first well region 121, the second well region 122, the isolation structures 110, the third well region 130, the gate structure 140, the first doping region 151, the second doping region 152 and the third doping region 153 in FIG. 2, can be referred to the above-mentioned descriptions in FIG. 1A-FIG. 1E, and are not repeated herein.

In addition, in this exemplified embodiment, the sidewalls of the third well region 130 is substantially aligned with two sides of the first isolation component 111. The third well region 130 may have a substantially symmetrical cross-sectional shape. However, the present disclosure is not limited thereto.

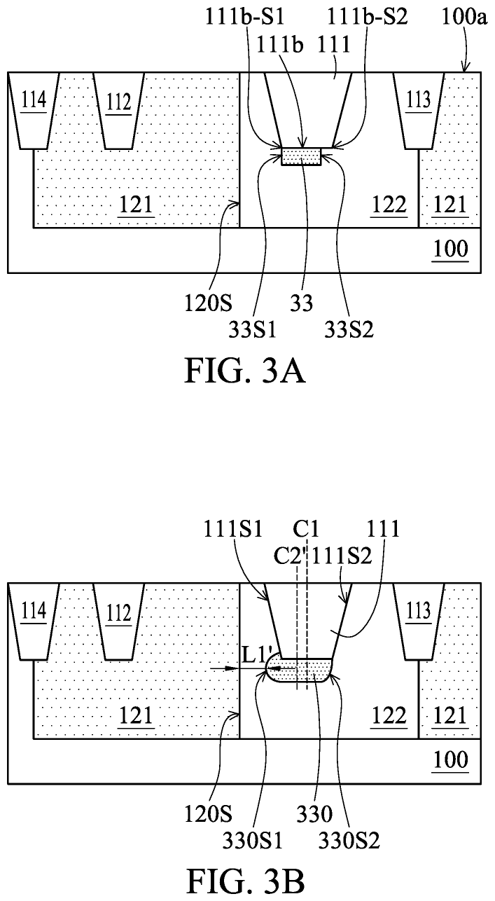

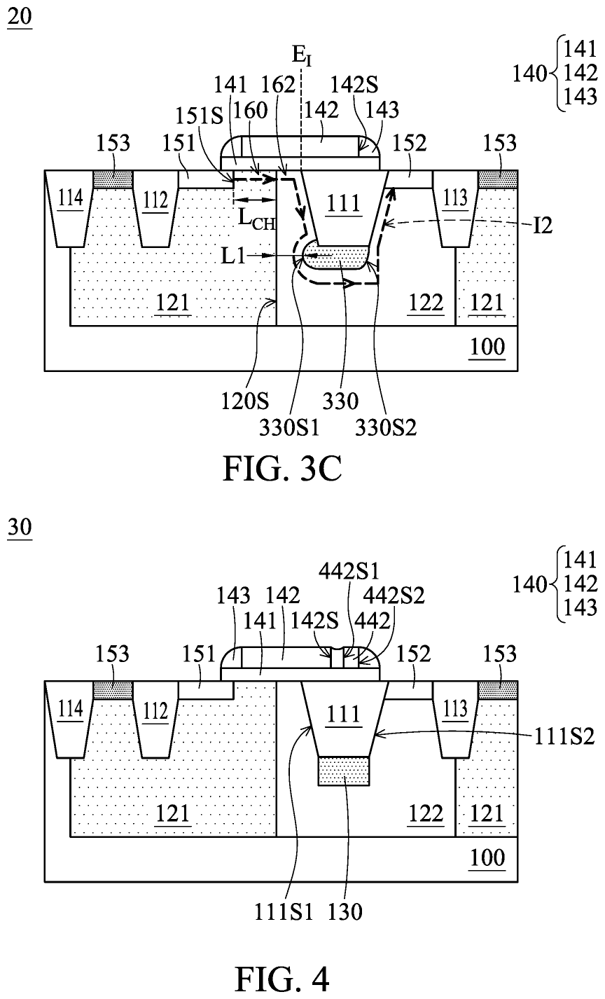

FIG. 3A-FIG. 3C illustrate cross-sectional views of intermediate stages of a method for forming a semiconductor device, in accordance with some embodiments of the present disclosure. The features/components in FIG. 3A-FIG. 3C similar or identical to the features/components in FIG. 1A-FIG. 1E are designated with similar or the same reference numbers. The details of those similar or the identical features/components can be referred to the above-mentioned descriptions and are not repeated herein.

In this exemplified embodiment, as shown in FIG. 1E, the opposite sidewalls of the third well region 130 are substantially aligned with the opposite sides of the bottom surface 111b of the first isolation component 111. However, the present disclosure is not limited thereto. In some embodiments, as shown in FIG. 3C, the opposite sidewalls of the third well region 330 are not aligned with the opposite sides of the bottom surface 111b of the first isolation component 111. Specifically, the third well region 330 has a side that is adjacent to the interface 120S between the first well region 121 and the second well region 122 protrudes from one side 111b-S1 of the bottom surface 111b of the first isolation component 111. In addition, the third well region 330 has an asymmetric cross-sectional shape.

Referring to FIG. 3A, dopants of the first conductivity type (for example, p-type) are implanted into a region 33 by ion implantation, in accordance with some embodiments of the present disclosure. The region 33 is adjacent to the bottom surface 111b of the first isolation component 111. The region 33 includes a first sidewall 33S1 that is closer to the second isolation component 112 and a second sidewall 33S2 that is closer to the third isolation component 113. In addition, in this exemplified embodiment, the first sidewall 33S1 of the region 33 is substantially aligned with the side 111b-S1 of the bottom surface 111b of the first isolation component 111, and the second sidewall 33S2 does not exceed the other side 111b-S2 of the bottom surface 111b of the first isolation component 111.

Details of the arrangement, materials and manufacturing methods of the components, such as the substrate 100, the first well region 121, the second well region 122, and the isolation structure 110 in FIG. 3A, can be referred to the above-mentioned descriptions in FIG. 1A-FIG. 1B, and are not repeated herein.

Referring to FIG. 3B, after the ion implantation is performed, a heat treatment, such as a rapid thermal annealing (RTA) process or another suitable method, is performed to activate the dopants of the first conductivity type (for example, p-type), in accordance with some embodiments of the present disclosure. Accordingly, the dopants diffuse outward to expand the region 33 to form a third well region 330.

In some embodiments, the third well region 330 includes a first sidewall 330S1 that is closer to the second isolation component 112 and a second sidewall 330S2 that is closer to the third isolation component 113. In some examples, the first sidewall 330S1 of the third well region 330 protrudes from the side 111b-S1 of the bottom surface 111b of the first isolation component 111, and the second sidewall 330S2 is, for example, substantially aligned with or retracted from the other side 111b-S2 of the bottom surface 111b. Specifically, in this exemplified embodiment, as shown in FIG. 3B, the third well region 330 covers and in direct contact with at least a portion of the bottom surface 111b of the first isolation component 111. The third well region 330 further extends to the sidewall 111S1 (i.e., the sidewall closer to the interface 120S between the first well region 121 and the second well region 122) of the first isolation component 111. The third well region 330 covers the lower portion of the first sidewall 111S1. Therefore, as shown in FIG. 3B, the first sidewall 130S1 of the third well region 330 protrudes from the first sidewall 111S1 of the first isolation component 111 and is closer to the interface of the 120S between the first well region 121 and the second well region 122, in accordance with some embodiments of the present disclosure.

In additional, as shown in FIG. 3B, the third well region 330 has an asymmetric cross-sectional shape, in accordance with some embodiments of the present disclosure. Specifically, the central line C1 of the first isolation component 111 is not aligned with the central line C2′ of the third well region 330. In this exemplified embodiment, the position of the third well region 330 is offset from the position of the overlying first isolation component 111.

Next, referring to FIG. 3C, a gate structure 140 is formed on the substrate 100, and a first doping region 151, a second doping region 152 and a third doping region 153 are subsequently formed, in accordance with some embodiments of the present disclosure. The gate structure 140 is formed above the third well region 130, and a channel region 160 of the semiconductor device 20 is between the sidewall 151S of the first doping region 151 and the interface 120S. Similar to the above exemplified embodiment in FIG. 1E, the channel region 160 in FIG. 3C under the gate structure 140 has a channel length LCH in the first direction D1. Details of the arrangement, materials and manufacturing methods of the components, such as the gate structure 140, the first doping region 151, the second doping region 152, and the third doping region 153 in FIG. 3C, can be referred to the above-mentioned descriptions in FIG. 1D-FIG. 1E, and are not repeated herein.

When the semiconductor device 20 is in operation, the current flows from the first doping region 151 (such as a source region of the semiconductor device) to the second doping region 152 (such as a drain region of the semiconductor device) by passing through the channel region 160 and the region 162 and along the sidewall of the first isolation component 111, the first sidewall 330S1 of the third well region 330, the bottom surface and the second sidewall 330S2 of the third well region 330 and the other sidewall of the first isolation component 111, in accordance with some embodiments of the present disclosure. The current flow direction is depicted by the dotted line 12 in FIG. 3C.

Therefore, in the semiconductor device 20 shown in FIG. 3C, the first sidewall 330S1 of the third well region 330 protrudes from the bottom surface 111b of the first isolation component 111, in accordance with some embodiments of the present disclosure. The first sidewall 330S1 of the third well region 330 is closer to the interface 120S between the first well region 121 and the second well region 122, thereby restricting the current flowing into the region 162 (positioned between the side edge E_{I} of the first isolation component 111 and the interface 120S). Accordingly, the current that flows into the second well region 122 (such as a drift region of the semiconductor device) can be reduced, thereby decreasing the on-current of the semiconductor device 20.

In addition, compared to the third well region 130 shown in FIG. 1E, the lateral distance L1′ between the third well region 330 in FIG. 3C and the interface 120S is less than the lateral distance L1 between the third well region 130 and the interface of 120S. Accordingly, in this exemplified embodiment, the on-current of the semiconductor device 20 in FIG. 3C is lower than the on-current of the semiconductor device 10 in FIG. 1E.

In addition, a shielding component can be formed above the substrate 100, in accordance with some embodiments of the present disclosure. The shielding component can be positioned above the third well region 330, so as to increase the breakdown voltage (BDV) of the semiconductor device.

FIG. 4 is a cross-sectional view of a semiconductor device 30 in accordance with some embodiments of the present disclosure. The features/components in FIG. 4 similar or identical to the features/components in FIG. 1A-FIG. 1E are designated with similar or the same reference numbers. The details of those similar or the identical features/components can be referred to the above-mentioned descriptions and are not repeated herein. In addition, details of the arrangement, materials and manufacturing methods of the components, such as the substrate 100, the first well region 121, the second well region 122, the isolation structures 110, the gate structure 140, the first doping region 151, the second doping region 152 and the third doping region 153 in FIG. 4, can be referred to the above-mentioned descriptions in FIG. 1A-FIG. 1E. The related contents are not repeated herein.

The difference between the semiconductor device 10 in FIG. 1E and the semiconductor device 30 in FIG. 4 is that a conductive portion 442 is formed over the substrate 100 and positioned on one side of the gate electrodes 142 of the gate structure 140. In some embodiments, the conductive portion 442 is correspondingly positioned above the first isolation component 111 and the third well region 130. Specifically, in this exemplified embodiment, the conductive portion 442 has a first sidewall 442S1 that is closer to the gate electrode 142 and a second sidewall 442S2 that is farther away from the gate electrode 142. As shown in FIG. 4, the second sidewall 442S2 of the conductive portion 442 does not protrude from the first isolation component 111.

In addition, the conductive portion 442 is disposed between the two opposite first sidewalls 111S1 and the second sidewall 111S2 of the first isolation component 111, in accordance with some embodiments of the present disclosure. That is, the conductive portion 442 is not positioned outside a region that is defined by the extension of the first sidewall 111S1 and a second sidewall 111S2 of the first isolation component 111. Therefore, in this exemplified embodiment, a vertical projection range of the first isolation component 111 on the substrate 100 covers a vertical projection range of the conductive portion 442 on the substrate 100.

In some embodiments, the conductive portion 442 and the gate electrode 142 may include the same material. The conductive portion 442 can be formed by removing a portion of the gate electrode material layer through a suitable patterning process and etching process, so that the remaining portions of the gate electrode material layer includes two individual parts that are separated from each other. The two individual parts serve as the gate electrode 142 and the conductive portion 442 respectively. Next, a gate spacer material layer is conformally deposited on the gate electrode 142 and the conductive portion 442. The gate spacer material layer covers the gate electrode 142 and the conductive portion 442 and fills the gap between the gate electrode 142 and the conductive portion 442. Next, a portion of the gate spacer material layer and a portion of the gate dielectric material layer are removed by using a suitable patterning process and etching process. The remaining portions of the gate spacer material layer form the gate spacers 143 and an insulating feature that fills between the gate electrode 142 and the conductive portion 442. The material of the conductive portion 442 can be referred to the related content of the gate electrode 142 described above, and are not repeated herein.

In addition, the conductive portion 442 is electrically isolated from the gate electrode 142, in accordance with some embodiments of the present disclosure. In some embodiments, the conductive portion 442 is grounded. For example, the conductive portion 442 can be electrically connected to the third doping region 153 (for example, serving as a bulk region of the semiconductor device) by connecting to the first well region 121. Alternatively, in some embodiments, the conductive portion 442 can be electrically connected to the second doping region 152 (serving as a drain region of the semiconductor device) to increase the breakdown voltage.

Although, FIG. 4 illustrates that the third well region 130 that has a substantially symmetrical cross-sectional shape (similar to the well region 130 in FIG. 1E) and is not offset from the overlying first isolation component 111, the present disclosure is not limit thereto. The semiconductor device may include the third well region 330 with an asymmetric cross-sectional shape as shown in FIG. 3C or a third well region with another cross-sectional shape, in accordance with some embodiments of the present disclosure. In addition, the third well region can be arranged in such a manner as to be offset from the overlying first isolation component 111. In some embodiments, the definition of offset arrangement is determined as the central line of the first isolation component 111 is not aligned with the central line of the third well region.

According to the aforementioned descriptions, the semiconductor devices and methods for forming the same, in accordance with some embodiments of the present disclosure, have many advantages. The semiconductor device includes a well region (such as the third well region 130 or 330) adjacent to an isolation component (such as the first isolation component 111 adjacent to the gate structure and the drain region). The well region and the drain region have different conductivity types to increase the on-resistance of the semiconductor device and decrease the on-current of the semiconductor device. For example, the well region is a p-type region. In some embodiments, the sidewall (for example, the first sidewall 130S1 or 330S1) of the third well region 130 or 330 is separated from the interface 120S that is between the first well region 121 and the second well region 122 under the gate structure 140 by a lateral distance L1 or L1′. The smaller the lateral distance L1 or L1′ is, the smaller the on-current of the semiconductor device is. By adjusting the lateral distance L1 or L1′ of the embodiment, the current that flows into the region 162 (that is located between the interface 120S and the side edge E_{I} of the first isolation component 111; see FIG. 1E) can be controlled, so that a predetermined on-current value of a semiconductor device in the application can be achieved. In addition, in some embodiments, the third well region that is formed in the semiconductor device does not occupy additional lateral space (for example, in the first direction D1) of the semiconductor device, and therefore does not increase the lateral size of the semiconductor device. That is, the on-current of the semiconductor device can be reduced without increasing the size (especially, the lateral dimension) of the semiconductor device, in accordance with some embodiments of the present disclosure.

In addition, the third well region 130 in some embodiments of the present disclosure can be aligned with (not offset) the first isolation component 111 as shown in FIG. 1E and FIG. 4. The third well region 130 in some other embodiments may be offset from the first isolation component 111 as shown in FIG. 3C. The disclosure has no limitation to the displacement of the third well region related to the first isolation component. In addition, the third well region 130 has a symmetrical cross-sectional shape, as shown in the exemplary embodiment of FIG. 1E. Alternatively, the third well region 330 has an asymmetric cross-sectional shape, as shown in the exemplary embodiment of FIG. 3C. The disclosure has no limitation to the cross-sectional shape of the third well region. In addition, in some embodiments, a shielding component can be formed on one side of the gate electrode 142. The shielding component is electrically insulated from the gate electrode 142. For example, the shielding component is a conductive portion 442 that is grounded (as shown in FIG. 4). In some embodiments, the shielding component is correspondingly positioned above the first isolation component 111 and the third well region 130, thereby increasing the breakdown voltage of the semiconductor device. In addition, the method for forming a semiconductor device in the embodiments has a relatively simple manufacturing process to form the semiconductor device with a third well region. The method of the embodiments is compatible with existing manufacturing processes. Therefore, the method of the embodiment is simple and does not require expensive manufacturing cost.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. In addition, the scope of the present disclosure is not limited to the processes, machine, manufacture, compositions, devices, operations and steps in the specific embodiments described in the specification. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure. In addition, each scope of the present disclosure constitutes an individual embodiment, and the scopes of the present disclosure include combinations of various application scopes and embodiments.

What is claimed is:

1. A semiconductor device, comprising:
a substrate having a first conductivity type;
a first well region, formed in the substrate and having the first conductivity type;
a second well region, formed in the substrate and having a second conductivity type;
an isolation component formed in the second well region;
a third well region formed in the second well region, wherein the third well region has the first conductivity type and is in contact with a bottom surface of the 9 isolation component;
a gate structure formed on the substrate, wherein the gate structure spans over the first well region and the second well region; and
a first doping region formed in the first well region and a second doping region formed in the second well region, wherein the first doping region and the second doping region have the second conductivity type and are disposed at opposite sides of the gate structure,
wherein an interface between the first well region and the second well region is positioned between the isolation component and the first doping region, and the interface is separated from the third well region by a lateral distance.

2. The semiconductor device as claimed in claim 1, wherein the third well region directly covers a portion of the bottom surface or the entire bottom surface of the isolation component.

3. The semiconductor device as claimed in claim 2, wherein the third well region has an asymmetric cross-sectional shape.

4. The semiconductor device as claimed in claim 1, wherein a doping concentration of the third well region is greater than a doping concentration of the second well region.

5. The semiconductor device as claimed in claim 1, wherein a doping concentration of the third well region is less than a doping concentration of the first well region.

6. The semiconductor device as claimed in claim 1, wherein the third well region is offset with respect to the isolation component.

7. The semiconductor device as claimed in claim 1, wherein the third well region includes:
a first sidewall adjacent to the first doping region; and
a second sidewall opposite to the first sidewall and adjacent to the second doping region,
wherein the first sidewall protrudes from a side of the bottom surface of the isolation component.

8. The semiconductor device as claimed in claim 7, wherein the second sidewall does not protrude from a different side of the bottom surface of the isolation component.

9. The semiconductor device as claimed in claim 7, wherein the first sidewall of the third well region is separated from the interface that is between the first well region and the second well region.

10. The semiconductor device as claimed in claim 1, wherein the third well region covers a portion of a sidewall of the isolation component, and the sidewall is adjacent to the first doping region.

11. The semiconductor device as claimed in claim 1, wherein the third well region is a strip-shaped region, and the first doping region, the third well and the second doping region extend in the same direction as viewed from a top of the substrate.

12. The semiconductor device as claimed in claim 1, wherein the third well region is electrically connected to the first well region.

13. The semiconductor device as claimed in claim 1, wherein the third well region is electrically insulated from the first well region.

14. The semiconductor device as claimed in claim 1, further comprising:
a conductive portion over the substrate and positioned at one side of a gate electrode of the gate structure, wherein the conductive portion is electrically insulated from the gate electrode, and
wherein the conductive portion is correspondingly positioned above the isolation component.

15. The semiconductor device as claimed in claim 14, wherein the conductive portion is correspondingly positioned above the third well region.

16. The semiconductor device as claimed in claim 14, wherein the conductive portion is grounded.

17. The semiconductor device as claimed in claim 1, further comprising:
a third doping region formed in the first well region, wherein the third doping region has the first conductivity type,
wherein the first doping region is disposed between the third doping region and the isolation component, and a doping concentration of the third well region is less than a doping concentration of the third doping region.

18. The semiconductor device as claimed in claim 17, wherein as viewed from a top of the substrate, the third doping region is a circular doping region and closely surrounds the first doping region, the gate structure, the second well region, the third well region and the second doping region.

19. The semiconductor device as claimed in claim 17, wherein the isolation component is a first isolation component, and the semiconductor device further comprises:
a second isolation component formed in the first well region, wherein the second isolation component is positioned between the third doping region and the first doping region,
wherein a bottom surface of the third well region is closer to a bottom surface of the substrate than a bottom surface of the second isolation component.

20. The semiconductor device as claimed in claim 19, further comprising:
a third isolation component formed in the first well region and the second well region, wherein the second doping region is positioned between the first isolation component and the third isolation component; and
a fourth isolation component formed in the first well region and the second well region, wherein the fourth isolation component and the third isolation component are disposed at the opposite sides of the gate structure, and the third doping region is positioned between the fourth isolation component and the second isolation component,
wherein the bottom surface of the third well region is closer to the bottom surface of the substrate than a bottom surface of the third isolation component and a bottom surface of the fourth isolation component.
